(19) United States
(12) Patent Application Publication
(10) Pub. No.: US 2003/0085415 A1
(43) Pub. Date: May 8, 2003

(54) CMOS image sensor device

(76) Inventors: Chong-Yao Chen, Chang Hua City (TW); Chen-Bin Lin, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,945

(22) Filed: Nov. 2, 2001

(51) Int. Cl. H01L 27/148

(52) U.S. Cl. 257/232

(57) ABSTRACT

A image sensor device is formed on a semiconductor wafer comprising a silicon substrate of a first conductive type. The image sensor device includes a photo sensor, an insulation layer, a MOS transistor and a deep doped region. The photo sensor is composed of a shallow doped region of a second conductive type. The shallow doped region is formed on a surface of the substrate and has a first predetermined depth. The insulation layer has a second predetermined depth and is positioned on the surface of the substrate to surround the photo sensor. The second predetermined depth is greater than the first predetermined depth. The MOS transistor is formed on the semiconductor wafer and electrically connected with the photo sensor. The deep doped region of the first conductive type is formed in the substrate under the insulation layer, and a dopant concentration of the deep doped region has a Gauss distribution.

### BACKGROUND OF INVENTION

1. Field of the invention

The present invention provides a complementary metal-oxide-semiconductor (CMOS) image sensor, and more particularly, a CMOS image sensor with an improvement in quantum efficiency and an elimination of cross talk effect.

2. Description of the prior art

Solid-state image sensors, such as a charge-coupled device (CCD) and a complementary metal-oxide-semiconductor (CMOS) image sensor, are commonly used as input devices for electronic video. Since a CMOS image sensor device is produced by using conventional semiconductor techniques, the CMOS image sensor has advantages of low cost and reduced device size.

Please refer to FIG. 1 and F_Hlt491850523i_Hlt491850523g.2. FIG. 1 is a top-view diagram of a prior CMOS image sensor on a semiconductor wafer. FIG. 2 is a cross sectional diagram along line AA of the semiconductor wafer shown in FIG. 1. The prior CMOS image sensor comprises three MOS transistors used as a reset MOS, a current source follower and a raw selector, respectively, and a photo-diode sensor for sensing the photo-intensity. As shown in FIG. 1 and FIG. 2, the prior image sensor is formed on a semiconductor wafer 10 composed of a positive-type (P-type) substrate 12. The surface of the P-type substrate 12 comprises a negative-channel (N-channel) area 30 for forming a negative-type MOS (NMOS) transistor 16 and a sensor area 32 for forming a photodiode sensor 34. Each MOS transistor can be directly formed on the substrate 12, or can be formed on a P-well (not shown) or an N-well (not shown) forming in the substrate 12.

The NMOS transistor 16 comprises a gate composed of a conductive layer 118. A spacer 22 is positioned around the gate. A LDD layer 20 formed by using a lightly doped drain (LDD) process and a HDD layer 24 formed by using a heavily doped drain (HDD) process are positioned in the substrate 12 at two sides of the gate. The HDD layers 24 function as a source and a drain of the NMOS transistor 16. The HDD layer 24 of the sensor area 32 and the HDD layer 24 of the NMOS transistor 16 are formed simultaneously. A depletion region is formed in a PN junction of the HDD layer 24 of the sensor area 32 and the P-type substrate 12, thus constructing the photo-diode sensor 34. Additionally, a shallow trench isolation (STI) structure 14 is formed surrounding the sensor area 32, and another P-well 13 is formed in the substrate 12 under each STI structure 14. The P-well 13 is used to prevent junction current of each photo-diode sensor from laterally drifting to neighboring image sensor to reduce a resolution of the image sensor.

In the prior CMOS image sensor structure, the sensor area 32 is composed of a deep HDD layer 24 so the depletion region of the photo-diode sensor 34 is positioned deeply in the substrate 12. However, when the depletion region accepts illumination of incident light and transfer photons to electric currents, the numbers of the incident photons attenuate with an increase of the incident depth. Especially for illumination of short wave lights (such as blue light), the sensitivity is reduced more seriously. In addition, the junction current occurring in the depletion region moves in the depths of the substrate 12, so the effect of the P-well 13 to resist a lateral drift of the junction current is limited and a cross talk effect is easily induced.

### SUMMARY OF INVENTION

It is therefore a primary objective of the present invention to provide a CMOS image sensor with an improvement in quantum efficiency and an elimination of the cross talk effect.

In a preferred embodiment, the present invention provides a complimentary metal oxide semiconductor (CMOS) image sensor device. The image sensor device is formed on a semiconductor wafer comprising a silicon substrate of a first conductive type. The image sensor device comprises a photo sensor, an insulation layer, a MOS transistor and a deep doped region. The photo sensor is composed of a shallow doped region of a second conductive type. The shallow doped region is formed on a surface of the substrate and has a first predetermined depth. The insulation layer has a second predetermined depth and is positioned on the surface of the substrate to surround the photo sensor. The second predetermined depth is greater than the first predetermined depth. The MOS transistor is formed on the semiconductor wafer and electrically connected with the photo sensor. The deep doped region of the first conductive type is formed in the substrate under the insulation layer, and a dopant concentration of the deep doped region has a Gauss distribution.

The CMOS image sensor of the present invention is composed of a shallow doped area, positioned near the surface of the substrate, used as a sensor area. So the photon quantity accepted by the sensor device will not decrease with the incident depth, especially for short wave lights with thinner skin depths. Therefore, the sensor device has higher quantum efficiency. In addition, the CMOS image sensor of the present invention has another deep doped region under the insulation layer, and a dopant concentration of the deep doped region has a Gauss distribution. So the junction current produced in the sensor area is effectively prevented from occurring a lateral drift to neighboring sensor devices, and thus the cross talk effect is eliminated.

### BRIEF DESCRIPTION OF DRAWINGS

FIG. 1 is a top-view diagram of an image sensor on a semiconductor wafer according to the prior art.

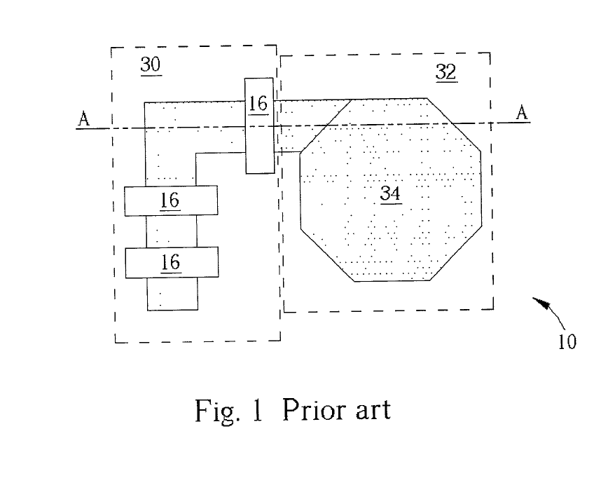

FIG. 2 is a cross sectional diagram along line AA of the semiconductor wafer shown in FIG. 1.

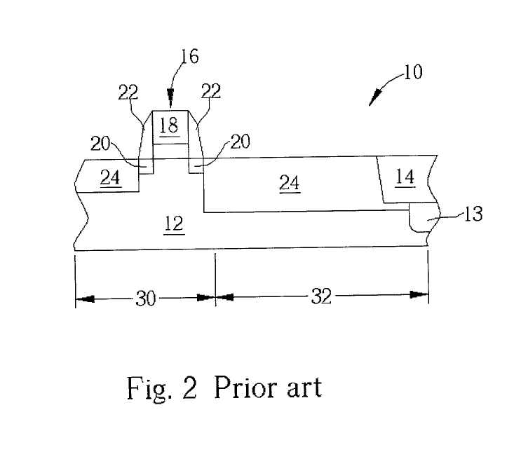

FIG. 3 is a top-view diagram of an image sensor on a semiconductor wafer according to the present invention.

FIG. 4 is a cross sectional diagram along line BB of the semiconductor wafer shown in FIG. 3.

### DETAILED DESCRIPTION

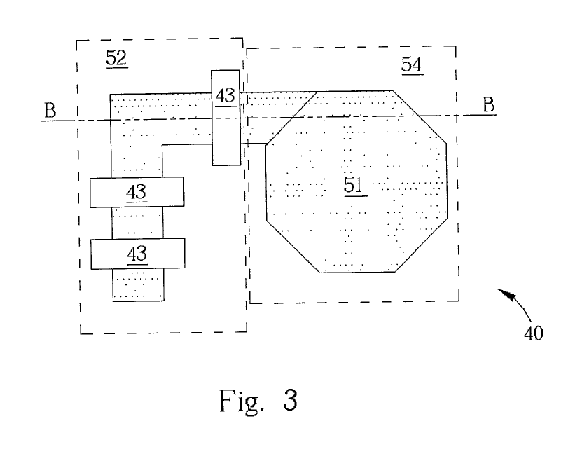

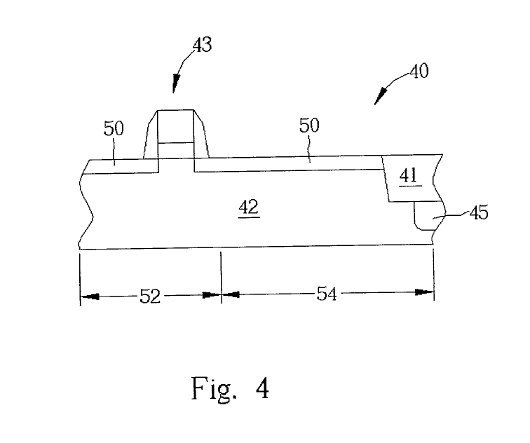

Please refer to FIG. 3 and FIG. 4. FIG. 3 is a top-view diagram of the present invention CMOS image sensor on a semiconductor wafer. FIG. 4 is a cross sectional diagram along line BB of the semiconductor wafer shown in FIG. 3. The present invention CMOS image sensor comprises three MOS transistors used as a reset MOS, a current source follower and a raw selector, respectively, and a photo-diode sensor for sensing the photo-intensity.

As shown in FIG. 3 and FIG. 4, in a preferred embodiment of the present invention, the image sensor is formed on a semiconductor wafer 40 composed of a positive-type (P-type) substrate 42. The surface of the P-type substrate 42 comprises a negative-channel (N-channel) area 52 for forming a negative-type MOS (NMOS) transistor 43 and a sensor area 54 for forming a photo-diode sensor 51. As shown in FIG. 4, the sensor area 54 in the structure of the present invention image sensor device is composed of a P-type shallow doped area 50 that is formed on the surface of the substrate 42 with a depth about 50˜1000 Å. In addition, an insulation layer with a depth of 400˜4000 Å is positioned on the surface of the substrate 42 and surrounds the sensor area 54. The insulation layer can be composed of a shallow trench isolation (STI) structure 41 or a field oxide layer (not shown).

The surface of the P-type substrate 42 of the present invention also comprises a P-type deep doped region 45 formed in the substrate 42 under the STI 41, and a dopant concentration of the deep doped region 45 has a Gauss distribution. Since the depth of the shallow doped region 50 is less than the depth of the insulation layer, the deep doped region 45 formed under the insulation layer is not adjacent to the shallow doped region 50.

In the structure of the present invention image sensor device, the shallow doped region constructing the sensor area is formed in the substrate near the surface of the wafer, so the interface between the shallow doped region and the substrate forms a depletion region near the surface of the substrate. Because the function of the depletion region is accepting photons and transferring photons to electrons so as to produce junction current, the numbers of the incident photons accepted by the depletion region will not attenuate for the incident lights piercing deeply into the substrate. As a result, the quantum efficiency of the present invention sensor device is improved. In addition, the dopant concentration of the deep doped region formed under the insulation layer surrounding the sensor area has a Gauss distribution. Therefore, the junction current produced in the sensor area is prevented form occurring a lateral drift to the neighboring sensor devices. As a result, the cross talk effect is prevented and the resolution of the sensor device is substantially increased.

In contrast to the structure of prior image sensor device, the structure of the present invention image sensor device uses a shallow doped region as a sensor area so as to improve the quantum efficiency of the sensor device. Furthermore, the present invention also forms a deep doped region of a doapnt concentration having a Gauss distribution under the insulation layer around the sensor area, so the cross talk effect is effectively prevented and the resolution of the image sensor device is increased.

What is claimed is:

1. A complimentary metal oxide semiconductor (CMOS) image sensor device, the image sensor device formed on a semiconductor wafer, the semiconductor wafer comprising a silicon substrate of a first conductive type, the image sensor device comprising:
a photo sensor composed of a shallow doped region of a second conductive type, the shallow doped region formed on a surface of the substrate and having a first predetermined depth;
an insulation layer having a second predetermined depth, positioned on the surface of the substrate, and surrounding the photo sensor, the second predetermined depth being greater than the first predetermined depth;
a MOS transistor formed on the semiconductor wafer and electrically connected with the photo sensor; and
a deep doped region of the first conductive type formed in the substrate under the insulation layer, a dopant concentration of the deep doped region having a Gauss distribution.

2. The CMOS image sensor device of claim 1 wherein the first conductive type is P-type and the second conductive type is N-type.

3. The CMOS image sensor device of claim 2 wherein the deep doped region is a P well and the depth of the P well is greater than 4000 Å.

4. The CMOS image sensor device of claim 1 wherein the first conductive type is N-type and the second conductive type is P-type.

5. The CMOS image sensor device of claim 4 wherein the deep doped region is a N well and the depth of the N well is greater than 4000 Å.

6. The CMOS image sensor device of claim 1 wherein the first predetermined depth is about 50˜1000 Å.

7. The CMOS image sensor device of claim 1 wherein the insulation layer comprises a shallow trench isolation (STI) structure or a field oxide layer.

8. The CMOS image sensor device of claim 1 wherein the second predetermined depth is about 400˜4000 Å.

9. The CMOS image sensor device of claim 1 wherein the deep doped region is used for preventing a cross talk effect caused by a junction current of the photo sensor diffusing to a neighboring sensor device.

10. The CMOS image sensor device of claim 1 wherein an interface between the shallow doped region and the substrate forms a depletion region which can receive photons and produce junction current by transforming photons into electrons, the depletion region being close to the surface of the substrate, a quantity of received photons not decreasing following an incident depth, such that a quantum efficiency of the sensor device is enhanced.

11. A complimentary metal oxide semiconductor (CMOS) image sensor device having high quantum efficiency and preventing a cross talk effect, the image sensor formed on a semiconductor wafer, the semiconductor wafer comprising a silicon substrate of a first conductive type, the image sensor device comprising:
a photo sensor composed of a shallow doped region of second conductive type, shallow doped region formed on a surface of the substrate and having a first predetermined depth;
an insulation layer having a second predetermined depth, positioned on the surface of the substrate, and surrounding the photo sensor, the second predetermined depth being greater than the first predetermined depth;
a MOS transistor formed on the semiconductor wafer and electrically connected with the photo sensor; and
a deep doped region of the first conductive type and formed in the substrate under the insulation layer, a dopant concentration of the deep doped region having a Gauss distribution for preventing the cross talk effect caused by a junction current of the photo sensor diffusing to a neighboring sensor device;
wherein an interface between the shallow doped region and the substrate forms a depletion region which can receive photons and produce junction current by transforming photons into electrons, the depletion region being close to the surface of the substrate, and a quantity of received photons not decreasing following an incident depth, such that the quantum efficiency of the sensor device is enhanced.

12. The CMOS image sensor device of claim 11 wherein the first conductive type is P-type and the second conductive type is N-type.

13. The CMOS image sensor device of claim 12 wherein the deep doped region is a P well and the depth of the P well is greater than 4000 Å.

14. The CMOS image sensor device of claim 11 wherein the first conductive type is N-type and the second conductive type is P-type.

15. The CMOS image sensor device of claim 14 wherein the deep doped region is a N well and the depth of the N well is greater than 4000 Å.

16. The CMOS image sensor device of claim 11 wherein the first predetermined depth is about 50˜1000 Å.

17. The CMOS image sensor device of claim 11 wherein the insulation layer comprises a shallow trench isolation (STI) structure or a field oxide layer.

18. The CMOS image sensor device of claim 11 wherein the second predetermined depth is about 400˜4000 Å.
